(19) United States
(12) Patent Application Publication
(10) Pub. No.: US 2010/0132991 A1
(43) Pub. Date: Jun. 3, 2010

(54) ELECTRONIC DEVICE, PRINTED CIRCUIT BOARD, AND ELECTRONIC COMPONENT

(75) Inventors: Minoru TAKIZAWA, Tokyo (JP); Hidenori TANAKA, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/552,244

(22) Filed: Sep. 1, 2009

(30) Foreign Application Priority Data
Nov. 28, 2008 (JP) 2008-305183

(51) Int. Cl. H05K 1/16

(52) U.S. Cl. 174/260

(57) ABSTRACT

According to one embodiment, an electronic device includes a housing, a printed circuit board, an electronic component, a bonding material, and chips. The printed circuit board is housed in the housing. The electronic component includes an electrode on a surface thereof that faces the printed circuit board. The bonding material is applied to at least part of the outer periphery of the electronic component on the printed circuit board to bond the electronic component to the printed circuit board. The chips are arranged at positions on the printed circuit board corresponding to the periphery of the surface of the electronic component to prevent the bonding material from intruding in a gap between the surface of the electronic component and the printed circuit board.

### CROSS-REFERENCE TO RELATED APPLICATIONS

This application is based upon and claims the benefit of priority from Japanese Patent Application No. 2008-305183, filed on Nov. 28, 2008, the entire contents of which are incorporated herein by reference.

### BACKGROUND

1. Field

One embodiment of the invention relates to an electronic device, a printed circuit board, and an electronic component.

2. Description of the Related Art

After the appearance of electronic components having a bottom-surface electrode structure, such as a ball grid array (BGA) package, a land grid array (LGA) package, and a chip size package (CSP), packages of such electronic components as having a bottom-surface electrode structure have been increasingly employed in various types of electronic devices. To mount an electronic component of this type on a printed circuit board, some measures need to be taken to prevent damage to the joint between the electronic component and the printed circuit board caused when the printed circuit board is subjected to an external stress. As one of the measures, there has been proposed a conventional method of applying a reinforcing adhesive around the electronic component to fix it to the printed circuit board. Besides, Japanese Patent Application Publication (KOKAI) No. 2001-291745 discloses another conventional method of providing a reinforcing plate between the electronic component and the printed circuit board.

If an electronic component such as BGA is fixed to a printed circuit board with an adhesive, the adhesive may flow into a gap between the electronic component and the printed circuit board. This lowers repairability for rework to remove the electronic component from the printed circuit board so that the printed circuit board can be reused. It is desirable to prevent the adhesive from being interposed between the electronic component and the printed circuit board to improve repairability as well as sufficiently reinforcing the joint. On the other hand, the use of a reinforcing plate results in higher costs.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a notebook personal computer (PC) according to an embodiment of the invention;

FIG. 2 is an exemplary perspective view of the inside of a housing of the notebook PC in the embodiment;

FIGS. 3A to 3C are exemplary side views of an electronic component according to a first embodiment of the invention;

FIG. 4 is an exemplary overhead view of the arrangement of chips in the first embodiment;

FIGS. 5A and 5B are exemplary overhead views of the arrangement of chips according to a second embodiment of the invention;

FIGS. 6A to 6C are exemplary side views of an electronic component according to a third embodiment of the invention;

FIGS. 7A to 7C are exemplary overhead views of the arrangement of chips in the third embodiment;

FIGS. 8A to 8C are exemplary side views of an electronic component according to a fourth embodiment of the invention;

FIGS. 9A to 9C are exemplary side views of an electronic component according to a fifth embodiment of the invention;

FIGS. 10A to 10C are exemplary overhead views of the arrangement of chips in the fifth embodiment;

FIGS. 11A to 11C are exemplary side views of an electronic component according to a sixth embodiment of the invention;

FIGS. 12A to 12C are exemplary overhead views of the arrangement of chips in the sixth embodiment;

FIGS. 13A to 13C are exemplary side views of an electronic component according to a seventh embodiment of the invention;

FIGS. 14A to 14C are exemplary overhead views of the arrangement of intrusion prevention components in the seventh embodiment;

FIGS. 15A to 15C are exemplary side views of an electronic component according to an eighth embodiment of the invention; and

FIGS. 16A to 16C are exemplary overhead views of the arrangement of the intrusion prevention components in the eighth embodiment.

### DETAILED DESCRIPTION

Various embodiments according to the invention will be described hereinafter with reference to the accompanying drawings. In general, according to one embodiment of the invention, an electronic device comprises a housing, a printed circuit board, an electronic component, a bonding material, and chips. The printed circuit board is configured to be housed in the housing. The electronic component comprises an electrode on a surface that faces the printed circuit board. The bonding material is configured to be applied to at least part of an outer periphery of the electronic component on the printed circuit board to bond the electronic component to the printed circuit board. The chips are configured to be arranged at positions on the printed circuit board corresponding to a periphery of the surface of the electronic component to prevent the bonding material from intruding in a gap between the surface of the electronic component and the printed circuit board.

According to another embodiment of the invention, an electronic device comprises a housing, a printed circuit board, an electronic component, a bonding material, and chips. The printed circuit board is configured to be housed in the housing. The electronic component comprises an electrode on a surface that faces the printed circuit board. The bonding material is configured to be applied to at least part of an outer periphery of the electronic component on the printed circuit board to bond the electronic component to the printed circuit board. The chips are configured to be arranged at positions on a periphery of the surface of the electronic component to prevent the bonding material from intruding in a gap between the surface of the electronic component and the printed circuit board.

According to still another embodiment of the invention, a printed circuit board comprises a chip configured to be arranged at a position corresponding to a periphery of a surface of an electronic component that faces the printed circuit board and that comprises an electrode. The chip prevents a bonding material from intruding in a gap between the surface of the electronic component and the printed circuit board.

According to still another embodiment of the invention, an electronic component comprises an electrode on a surface that faces a printed circuit board, and a chip configured to be arranged at a position on a periphery of the surface to prevent a bonding material from intruding in a gap between the surface and the printed circuit board.

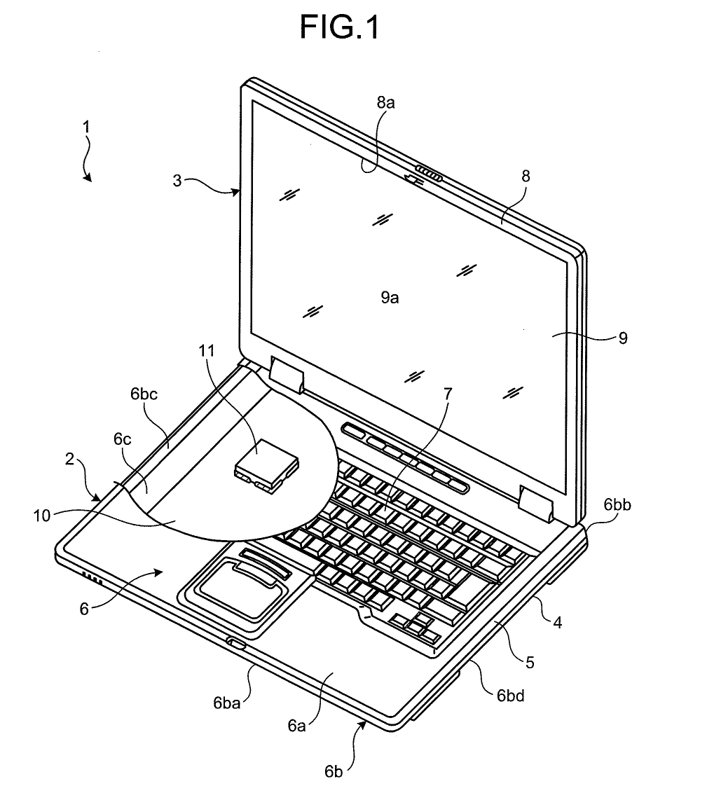

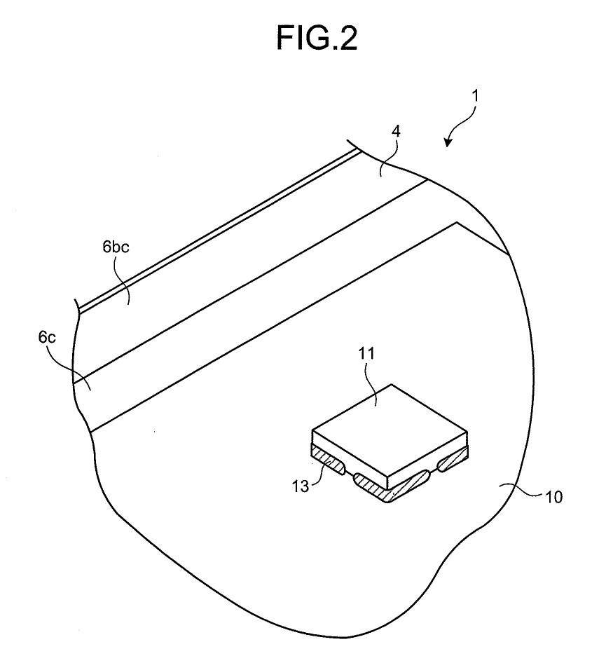

With reference to FIGS. 1 and 2, a description will be given of a configuration of an electronic device provided with a printed circuit board or an electronic component having a bottom-surface electrode structure according to an embodiment of the invention. In the following, the electronic device will be described as a notebook personal computer (PC) by way of example and without limitation; however, it can be other electronic devices such as a digital camera, a video camera, a personal digital assistant, a television receiver, and a recorder. FIG. 1 is a perspective view of a notebook PC 1 according to the embodiment. FIG. 2 is a perspective view of the inside of a housing 6 of the notebook PC 1.

The notebook PC 1 of the embodiment comprises a main body 2 and a display module 3.

The main body 2 comprises a base 4 and a cover 5. The cover 5 is fitted on the base 4. A combination of the base 4 and the cover 5 provides the main body 2 with the housing 6 formed in a box shape.

The housing 6 has a top wall 6a, a side wall 6b, and a bottom wall 6c. Supported on the top wall 6a is a keyboard 7. The side wall 6b includes a front side wall 6ba, a rear side wall 6bb, a left side wall 6bc and a right side wall 6bd.

The display module 3 comprises a display housing 8 and a liquid crystal display (LCD) panel 9 housed in the display housing 8. The LCD panel 9 is provided with a display screen 9a. The display housing 8 has an opening 8a on its surface so that the display screen 9a is exposed to the outside thereof through the opening 8a.

The display module 3 is hingedly supported on the rear edge of the housing 6. This allows the display module 3 to rotate between a closed position and an open position. The display module 3 lies and covers over the top wall 6a in the closed position, while it stands to expose the top wall 6a in the open position.

The housing 6 houses a printed wiring board (PWB) 10 and an electronic component 11 having a bottom-surface electrode structure such as BGA, LGA, and CSP. Although, for simplicity, only one electronic component (11) is illustrated in FIG. 1, a plurality of electronic components are generally mounted on the PWB 10.

The PWB 10 comprises an insulating board on which a circuit pattern is printed with a conductive material such as copper foil. Having the electronic component 11 and chips 12, which will be described later, mounted and soldered thereon, the PWB 10 functions as a printed circuit board.

The electronic component 11 is a surface-mountable electronic component that needs neither a lead nor a pin for electrically connecting to the PWB 10. The electronic component 11 is mounted on the PWB 10 adjacent to each other.

As examples of a package of the electronic component 11 may be cited a BGA package, an LGA package, and a CSP. The “BGA package” refers herein to a leadless surface-mountable package, on the bottom surface of which bumps such as solder balls are arranged in a grid by a dispenser. The BGA package is used in reflow soldering. The “LGA package” refers herein to a package having no bump such as a solder ball. The “CSP” refers herein to a type of semiconductor chip package that is equal in size to a chip or slightly larger than the chip.

Examples of the electronic component 11 include, but are not limited to, large-scale integration (LSI) such as a central processing unit (CPU) and a graphics processing unit (GPU). In addition to the examples cited above, any other electronic components may be the electronic component 11.

Around the four corners (or a pair of diagonal corners) of the electronic component 11 mounted on the PWB 10, an adhesive 13 is applied in an L-like shape along the outer periphery to bond the electronic component 11 to the PWB 10. The adhesive 13 is an insulating resin used for the mounting of the electronic component 11, and bonds the electronic component 11 to the PWB 10. The adhesive 13 is capable of reducing external stress on bumps, which serve as the joint between the PWB 10 and the electronic component 11, due to the impact from the fall of the notebook PC 1, the deformation or warping of the PWB 10, or the like.

As described above, the adhesive 13 is applied around the corners of the electronic component 11 along the outer periphery. This is because bumps located at the outermost periphery, especially those located at the four corners, are more likely to be damaged by, for example, a crack or suffered from poor connection caused by external stress due to the impact from the fall of the notebook PC 1 or the like. Although the adhesive 13 is illustrated in FIGS. 1 and 2 as applied around the respective corners (four corners) of the electronic component 11 along the outer periphery, it may be applied around a pair of diagonal corners of the electronic component 11 along the outer periphery. In this case also, the same effect can be achieved. Alternatively, the adhesive 13 may be applied over the entire outer periphery of the electronic component 11.

A description will now be given of the electronic component 11 according to various embodiments of the invention.

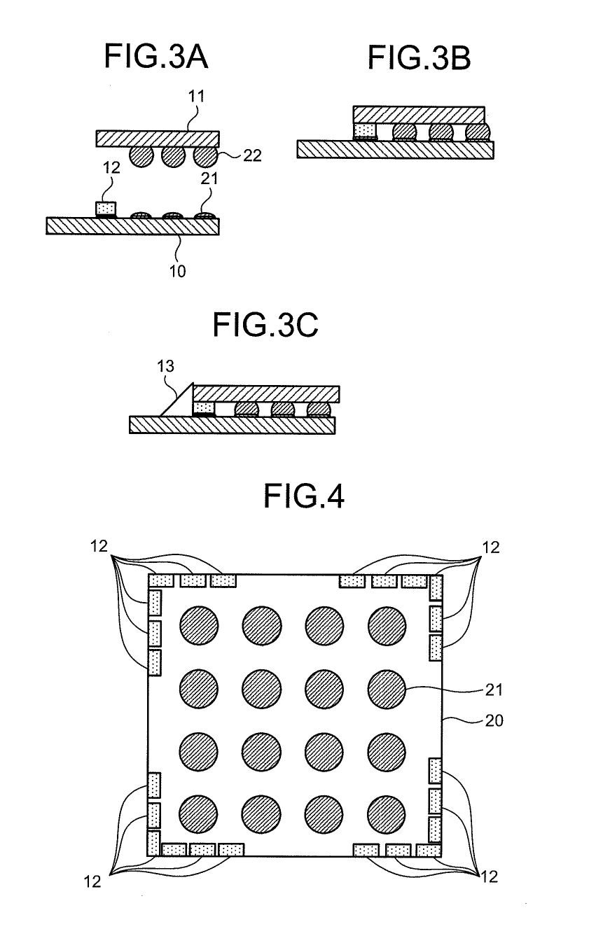

FIGS. 3A to 3C are side views of the electronic component 11 according to a first embodiment of the invention. FIG. 4 is an overhead view of the arrangement of the chips 12 according to the first embodiment.

As illustrated in FIG. 3A, the chips 12 are mounted and soldered in advance to predetermined positions, which will be described later, on the PWB 10. Then, as illustrated in FIG. 3B, the electronic component 11 is mounted on the PWB 10, to which the chips 12 have already been soldered, by soldering solder balls 22 to PWB electrodes 21 through reflow soldering. Further, as illustrated in FIG. 3C, the adhesive 13 is applied along the outer periphery of the corners of the electronic component 11 to reinforce the joint between the electronic component 11 and the PWB 10. As can be seen from FIG. 3C, the chips 12 prevent the adhesive 13 from being interposed in a gap between the PWB 10 and the electronic component 11. In this manner, the chips 12 serve as a bank to prevent the adhesive 13 from intruding in the gap.

It is assumed herein that the chips 12 have a height that allows them to be accommodated in the gap between the PWB 10 and the electronic component 11 after the reflow soldering. The chips 12 may be low-cost chips, such as, for example, resistors with sizes of 0402, 0603, and 1005, or capacitors. Besides, the chips 12 may be used as circuit components, and, for example, the resistance of the chips 12 may act as a damping resistance.

FIG. 4 illustrates the arrangement of the chips 12. With reference to FIG. 4, the chips 12 are located at the four corners along the periphery of a region 20 of the surface of the PWB 10 on which the electronic component 11 is mounted. The region 20 is generally rectangular in shape. The plurality of the chips 12 are arranged in an L-like shape as illustrated in FIG. 4. When the chips 12 are electrically connected to the PWB 10 so that they can function as circuit elements, wiring is provided to the positions of the chips 12 on the PWB 10. Incidentally, a space of 0.15 mm to 0.25 mm is present between each adjacent pair of the chips 12 because of the circuit pattern.

As described above, when the chips 12 are used only as a bank to prevent the adhesive 13 from intruding in the gap, wiring does not need to be provided on the PWB 10. As illustrated in FIGS. 1 and 2, the adhesive 13 is applied in an L-like shape along the outer side of where the chips 12 are arranged on the region 20 of the PWB 10 around the outer periphery of each of the four corners of the electronic component 11.

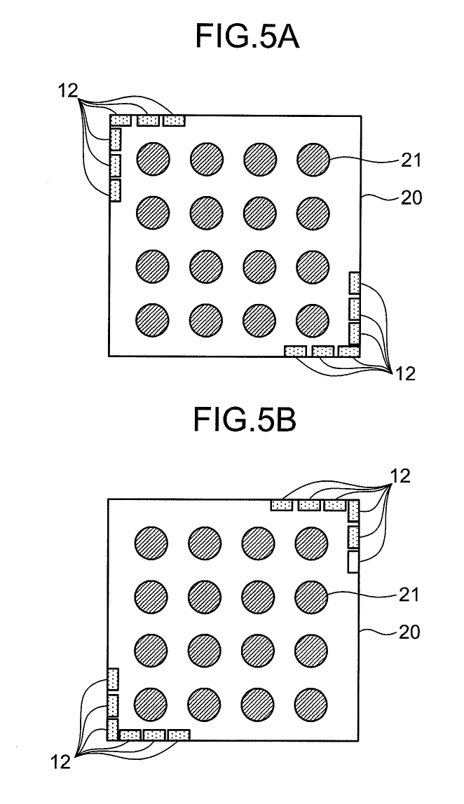

FIG. 5 is an overhead view of the arrangement of the chips 12 according to a second embodiment of the invention. In the first embodiment described above, the chips 12 are located at the four corners along the periphery of the region 20 of the PWB 10 on which the electronic component 11 is mounted. On the other hand, according to the second embodiment, as illustrated in FIGS. 5A and 5B, the chips 12 are located at only a pair of diagonal corners among the four corners along the periphery of the region 20 of the PWB 10 on which the electronic component 11 is mounted. Further, differently from the first embodiment, the adhesive 13 is applied only around the outer periphery of the pair of diagonal corners. According to the second embodiment, it is also possible to prevent the adhesive 13 from intruding in the gap between the PWB 10 and the electronic component 11 as well as to reinforce the joint at a desired level.

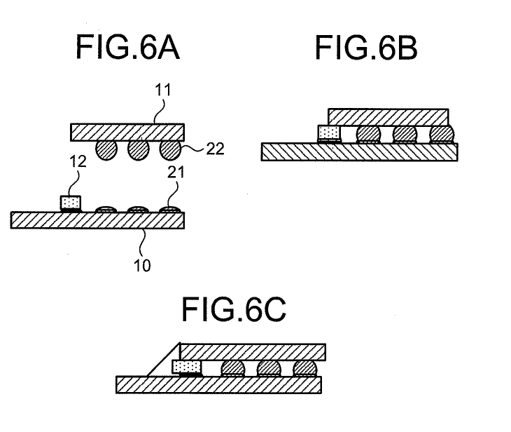

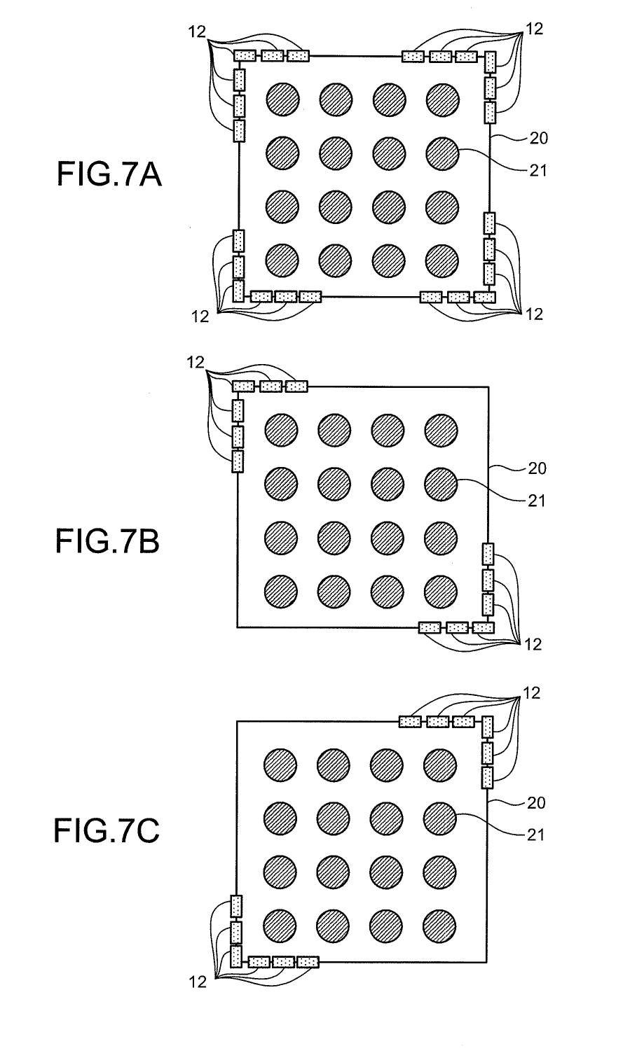

FIGS. 6A to 6C are side views of the electronic component 11 according to a third embodiment of the invention. FIGS. 7A to 7C are overhead views of the arrangement of the chips 12 according to the third embodiment. In the first and second embodiments described above, each of the chips 12 is located entirely within the region 20 on which the electronic component 11 is mounted. On the other hand, according to the third embodiment, as can be seen from FIGS. 6A to 6C and FIGS. 7A to 7C, each of the chips 12 is arranged such that part thereof is located within the region 20 on which the electronic component 11 is mounted, and the remaining part is located outside the region 20. Otherwise, the third embodiment is similar to the first and second embodiments. According to the third embodiment, it is also possible to prevent the adhesive 13 from intruding in the gap between the PWB 10 and the electronic component 11 as well as to reinforce the joint at a desired level.

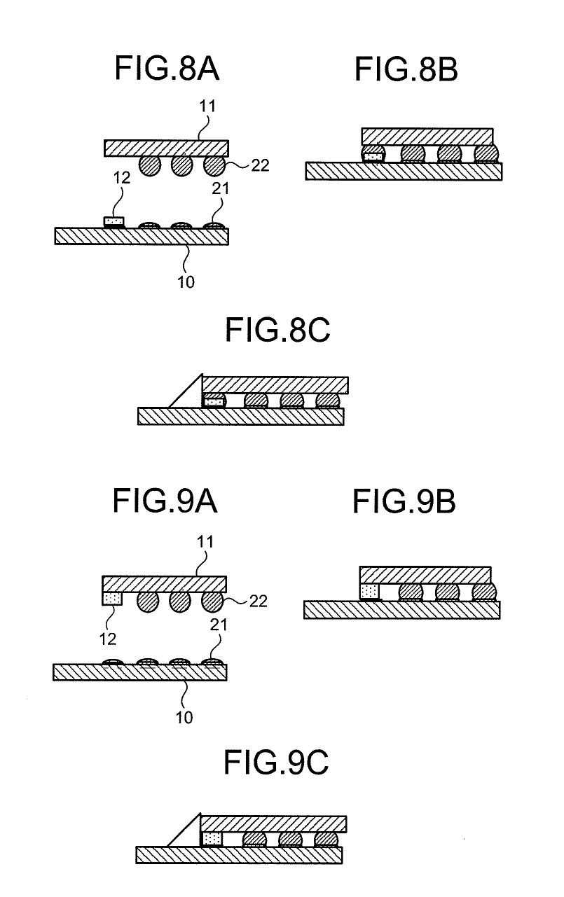

FIGS. 8A to 8C are side views of the electronic component 11 according to a fourth embodiment of the invention. In the first embodiment previously described in connection with FIGS. 3A to 3C, the chips 12 have a height that does not create a gap between the chips 12 and the electronic component 11. However, a gap maybe caused between the chips 12 and the electronic component 11 depending on the height of the chips 12. Further, although it is preferable that the chips 12 have the same height, they may be of different types and thus have different heights. The difference in height also causes a gap between the chips 12 and the electronic component 11. According to the fourth embodiment, such a gap is filled with solder as illustrated in FIGS. 8A to 8C. Otherwise, the fourth embodiment is similar to the first to third embodiments.

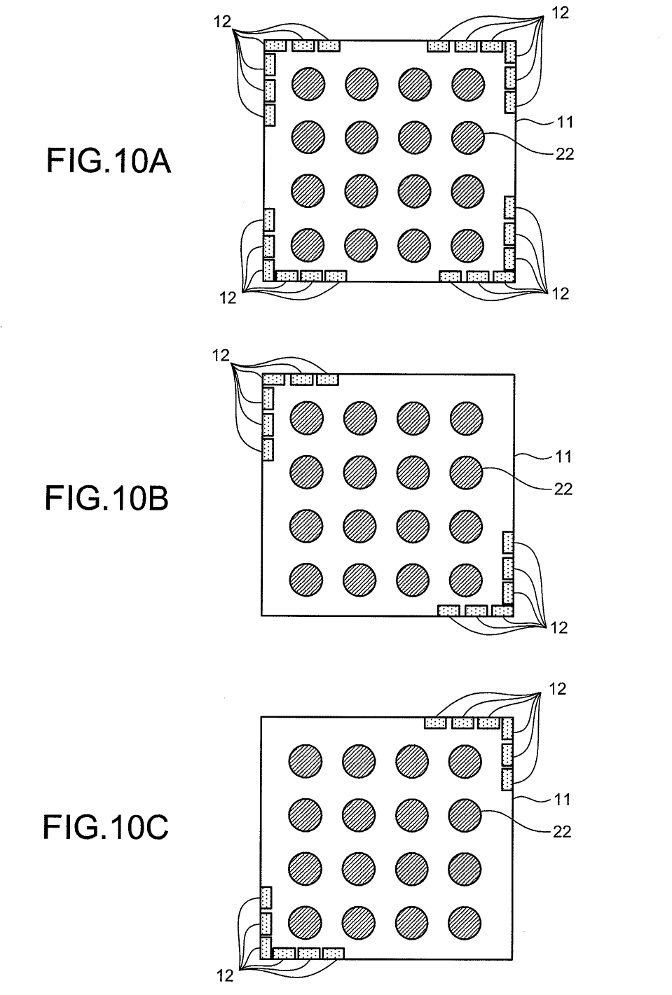

FIGS. 9A to 9C are side views of the electronic component 11 according to a fifth embodiment of the invention. FIGS. 10A to 10C are overhead views of the arrangement of the chips 12 according to the fifth embodiment. In the first to fourth embodiments described above, the chips 12 are mounted and soldered in advance to the PWB 10. On the other hand, according to the fifth embodiment, with an adhesive or the like, the chips 12 are bonded in advance to the four corners (see FIG. 10A) or a pair of diagonal corners (see FIGS. 10B and 10C) at the periphery of the surface of the electronic component 11. The chips 12 are soldered to the PWB 10 together with the electronic component 11 through reflow soldering. Otherwise, the fifth embodiment is similar to the first to fourth embodiments. When the chips 12 are electrically connected to the PWB 10 so that they can function as circuit elements, wiring is provided to the positions of the chips 12 on the PWB 10. Incidentally, a space of 0.15 mm to 0.25 mm is present between each adjacent pair of the chips 12 because of the circuit pattern.

According to the fifth embodiment, the chips 12 also prevent the adhesive 13 from being interposed in the gap between the PWB 10 and the electronic component 11, and serve as a bank to prevent the adhesive 13 from intruding in the gap as can be seen from FIG. 9C. The chips 12 are bonded in advance to the electronic component 11, and therefore a gap is not formed between the chips 12 and the electronic component 11. A gap formed between the chips 12 and the electrode side of the PWB 10 is filled with solder.

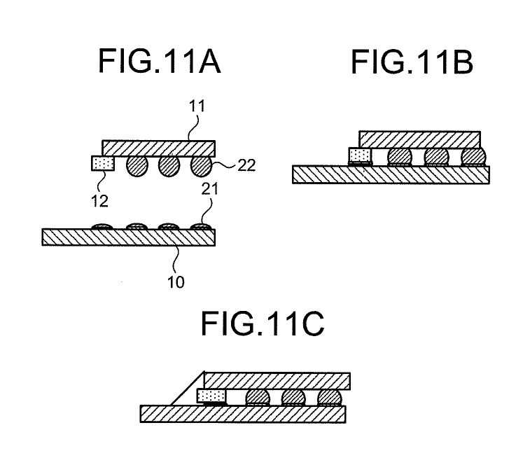

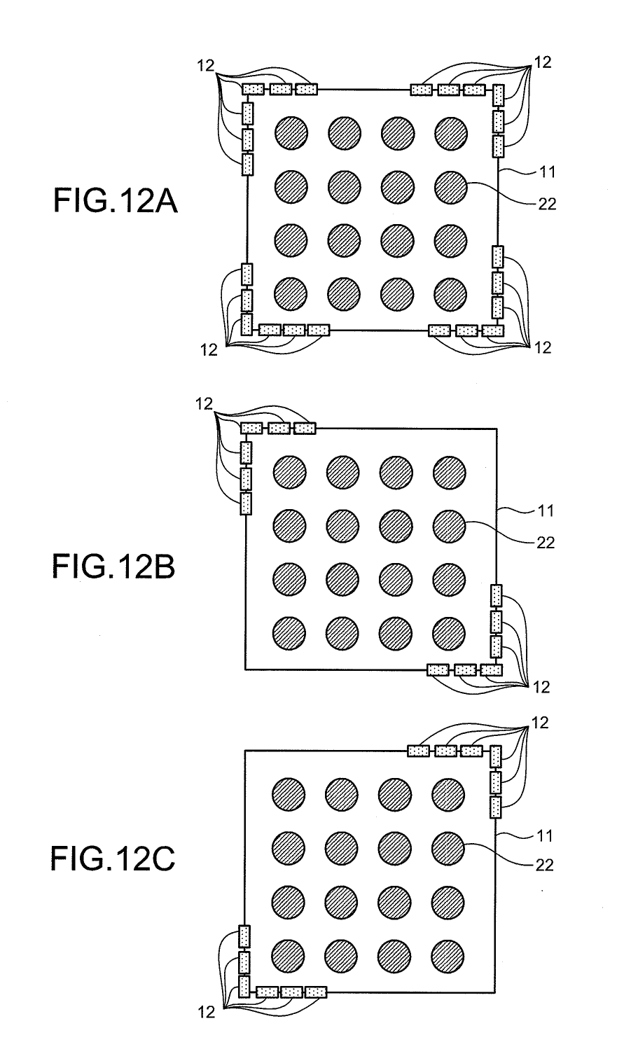

FIGS. 11A to 11C are side views of the electronic component 11 according to a sixth embodiment of the invention. FIGS. 12A to 12C are overhead views of the arrangement of the chips 12 according to the sixth embodiment. In the fifth embodiment described above, each of the chips 12 is located entirely within the four corners or a pair of diagonal corners at the periphery of the surface of the electronic component 11. On the other hand, according to the sixth embodiment, as can be seen from FIGS. 11A to 11C and FIGS. 12A to 12C, each of the chips 12 is arranged such that part thereof is located within the four corners or a pair of diagonal corners at the periphery of the surface of the electronic component 11, and the remaining part is located outside the corners. Otherwise, the sixth embodiment is similar to the fifth embodiment. According to the sixth embodiment, it is also possible to prevent the adhesive 13 from intruding in the gap between the PWB 10 and the electronic component 11 as well as to reinforce the joint at a desired level.

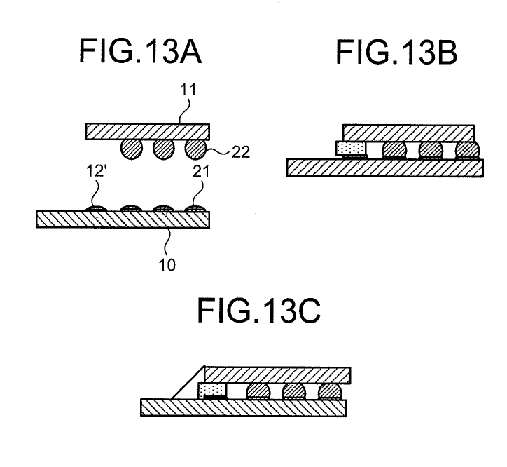

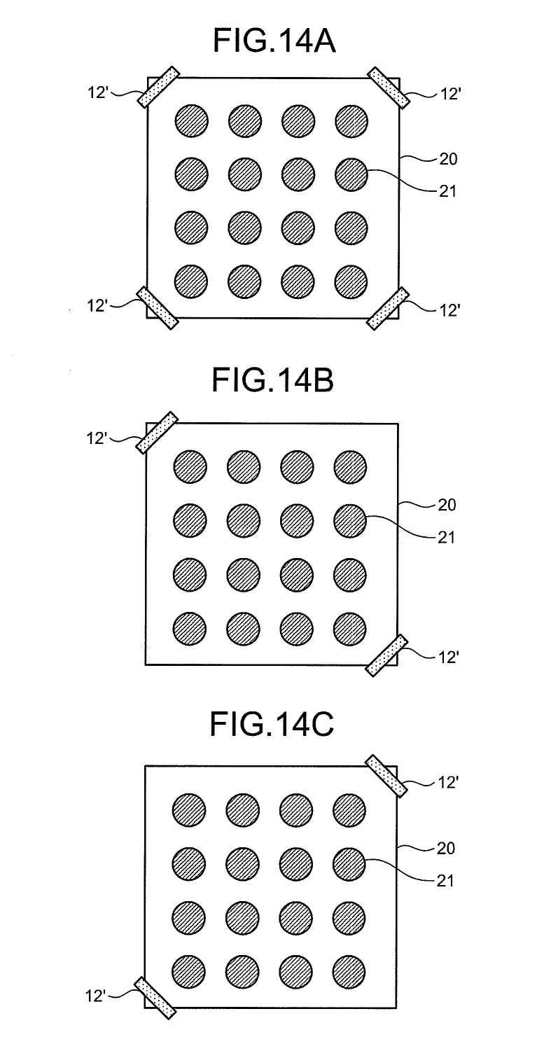

FIGS. 13A to 13C are side views of the electronic component 11 according to a seventh embodiment of the invention. FIGS. 14A to 14C are overhead views of the arrangement of the chips 12 according to the seventh embodiment. As illustrated in FIG. 13A, intrusion prevention components 12′ formed of, for example, wood or metal are mounted in advance on a predetermined position, which will be described later, of the PWB 10 to prevent the adhesive 13 from intruding in the gap. According to the material, the intrusion prevention components 12′ are bonded to the PWB 10 with an adhesive or soldered to the land thereof. Then, as illustrated in FIG. 13B, the electronic component 11 is mounted on the PWB 10, on which the intrusion prevention components 12′ have already been mounted, by soldering the solder balls 22 to the PWB electrodes 21 through reflow soldering. Further, as illustrated in FIG. 13C, the adhesive 13 is applied to reinforce the joint between the electronic component 11 and the PWB 10. As can be seen from FIG. 13C, the intrusion prevention components 12′ prevent the adhesive 13 from being interposed in the gap between the PWB 10 and the electronic component 11. In this manner, the intrusion prevention components 12′ serve as a bank to prevent the adhesive 13 from intruding in the gap. Incidentally, it is assumed herein that the chips 12 have a height that allows them to be accommodated in the gap between the PWB 10 and the electronic component 11 after the reflow soldering.

FIGS. 14A to 14C illustrate the arrangement of the intrusion prevention components 12′. With reference to FIGS. 14A to 14C, the intrusion prevention components 12′ are located at the four corners or a pair of diagonal corners along the periphery of the region 20 of the PWB 10 on which the electronic component 11 is mounted. The region 20 is generally rectangular in shape. The intrusion prevention components 12′ are arranged diagonally with respect to the sides of the region 20 at the four corners or a pair of diagonal corners thereof as illustrated in FIGS. 14A to 14C. As just described, the intrusion prevention components 12′ are used as a bank to prevent the adhesive 13 from intruding in the gap.

As illustrated in FIGS. 1 and 2, the adhesive 13 is applied along the outer side of where the intrusion prevention components 12′ are arranged on the region 20 of the PWB 10 around the outer periphery of each of the four corners or a pair of diagonal corners of the electronic component 11. While, in the example of FIGS. 14A to 14C, the intrusion prevention components 12′ are illustrated as having a rectangular shape, their shape is not limited to the rectangular design. The intrusion prevention components 12′ may have an L-like shape corresponding to a shape in which the chips 12 are arranged as described previously in the first to fourth embodiments, or any other shapes. Besides, each of the intrusion prevention components 12′ may be arranged such that part thereof is located within the region 20 as illustrated in FIGS. 14A to 14C or may be arranged entirely within the region 20. It is assumed herein that the intrusion prevention components 12′ have a height that allows them to be accommodated in the gap between the PWB 10 and the electronic component 11 after the reflow soldering. Preferably, the intrusion prevention components 12′ have a height that does not cause a gap between them and the bottom surface of the electronic component 11.

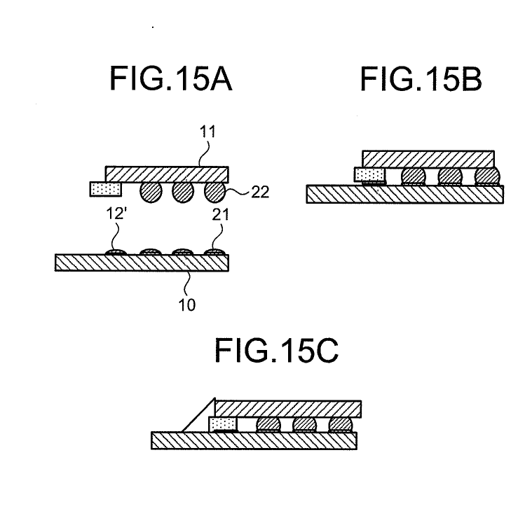

FIGS. 15A to 15C are side views of the electronic component 11 according to an eighth embodiment of the invention. In the seventh embodiment described above, the intrusion prevention components 12′ are bonded in advance to the PWB 10. On the other hand, according to the eighth embodiment, with an adhesive or the like according to the material, the intrusion prevention components 12′ are bonded in advance to the periphery of the surface of the electronic component 11.

The intrusion prevention components 12′ also prevent the adhesive 13 from being interposed in the gap between the PWB 10 and the electronic component 11, and serve as a bank to prevent the adhesive 13 from intruding in the gap as can be seen from FIG. 15C. The intrusion prevention components 12′ are bonded in advance to the electronic component 11, and therefore a gap is not formed between the intrusion prevention components 12′ and the electronic component 11. It is assumed herein that the intrusion prevention components 12′ have a height that allows them to be accommodated in the gap between the PWB 10 and the electronic component 11 after the reflow soldering. Preferably, the intrusion prevention components 12′ have a height that does not cause a gap between them and the bottom surface of the electronic component 11.

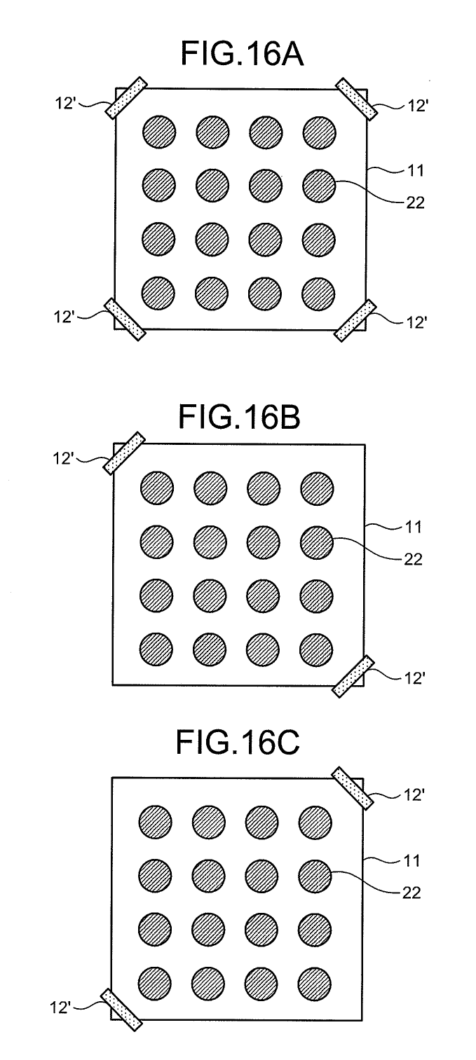

FIGS. 16A to 16C illustrate the arrangement of the intrusion prevention components 12′. With reference to FIGS. 16A to 16C, the intrusion prevention components 12′ are located at the four corners or a pair of diagonal corners at the periphery the surface of the electronic component 11. In addition, the intrusion prevention components 12′ are arranged diagonally with respect to the sides of the electronic component 11 at the four corners or a pair of diagonal corners thereof as illustrated in FIGS. 16A to 16C. While, in the example of FIGS. 16A to 16C, each of the intrusion prevention components 12′ is arranged such that part thereof is located within the surface of the electronic component 11 and the remaining part is located outside the surface, it may be arranged entirely within the surface. In this manner, the intrusion prevention components 12′ are used as a bank to prevent the adhesive 13 from intruding in the gap, and therefore wiring does not need to be provided on the PWB 10 for the intrusion prevention components 12′.

As described above, according to the embodiments, the chips 12 or the intrusion prevention components 12′ are provided to the PWB 10 or the electronic component 11 to prevent the adhesive 13 from intruding in the gap between the PWB 10 and the electronic component 11. This as a result facilitates rework. Moreover, by using low-cost components such as low-cost resistors or capacitors as the chips 12, the cost can be reduced.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a printed circuit board in the housing;
an electronic component comprising an electrode on a surface facing the printed circuit board;
an adhesive material applied to at least a portion of an outer periphery of the electronic component on the printed circuit board in order to attach the electronic component to the printed circuit board; and
chips at positions on the printed circuit board corresponding to a periphery of the surface of the electronic component configured to prevent the adhesive material from intruding in a gap between the surface of the electronic component and the printed circuit board.

2. The electronic device of claim 1, wherein
the chips are at the positions corresponding to either four corners or diagonal two corners of the surface of the electronic component, and
the adhesive material is applied to portions corresponding to the chips.

3. The electronic device of claim 2, wherein each of the chips is on the printed circuit board such that at least a portion of the chip is between the surface of the electronic component and the printed circuit board.

4. The electronic device of claim 1, wherein a gap between the chips and at least one of the electronic component and the printed circuit board is filled with solder.

5. An electronic device comprising:
a housing;
a printed circuit board in the housing;
an electronic component comprising an electrode on a surface facing the printed circuit board;
an adhesive material applied to at least a portion of an outer periphery of the electronic component on the printed circuit board in order to attach the electronic component to the printed circuit board; and
chips at positions on a periphery of the surface of the electronic component in order to prevent the adhesive material from intruding in a gap between the surface of the electronic component and the printed circuit board.

6. The electronic device of claim 5, wherein
the chips are at either four corners or diagonal two corners of the surface of the electronic component, and
the adhesive material is applied to portions corresponding to the chips.

7. The electronic device of claim 6, wherein each of the chips is on the surface of the electronic component such that at least a portion of the chip is between the surface of the electronic component and the printed circuit board.

8. The electronic device of claim 5, wherein a gap between the chips and the printed circuit board is filled with solder.

9. A printed circuit board comprising a chip at a position corresponding to a periphery of a surface of an electronic component in order to prevent an adhesive material from intruding in a gap between the surface of the electronic component and the printed circuit board, the surface of the electronic component facing the printed circuit board and comprising an electrode.
